(19) United States
(12) Patent Application Publication
(10) Pub. No.: US 2025/0165396 A1
(43) Pub. Date: May 22, 2025

(54) ARTIFICIAL NEURAL NETWORK FOR IMPROVING PERFORMANCE OF COMPUTER MEMORY SYSTEM

(71) Applicant: InnoGrit Technologies Co., Ltd., Shanghai (CN)

(72) Inventors: Chenrong Xiong, San Jose, CA (US); Bo Fu, Cupertino, CA (US)

(21) Appl. No.: 18/908,602

(22) Filed: Oct. 7, 2024

Related U.S. Application Data
(60) Provisional application No. 63/601,822, filed on Nov. 22, 2023.

(51) Int. Cl. G06F 12/06

(52) U.S. Cl. CPC G06F 12/0646

(57) ABSTRACT

A controller is configured to generate configuration parameters using an artificial neural network and to use the configuration parameters in interacting with a non-volatile memory. At least one of the configuration parameters is not a threshold voltage for reading the non-volatile memory. The controller is configured to implement the artificial neural network. The controller may have a prediction buffer configured to store multiple sets of configuration parameters generated by the artificial neural network. The controller may select one of the sets as the configuration parameters.

### CROSS-REFERENCE TO RELATED APPLICATIONS

This application claims priority to U.S. Provisional Application No. 63/601,822, filed on Nov. 22, 2023, the entire disclosure thereof hereby incorporated by reference.

### BACKGROUND

Improving the performance of a computer memory system is beneficial for enhancing overall system efficiency. By enhancing the performance of the memory system, the computer can process tasks more swiftly, leading to better multitasking capabilities, faster load times for applications, and improved overall user experience. Additionally, a more efficient memory system can contribute to energy savings and prolong the lifespan of the computer hardware. Therefore, the need to improve the performance of a computer memory system is beneficial for keeping pace with evolving technological demands and realizing optimal computing performance.

### SUMMARY

Disclosed herein is a controller configured to generate M configuration parameters using an artificial neural network, M being a positive integer, and configured to use the M configuration parameters in interacting with a non-volatile memory. At least one of the M configuration parameters is not a threshold voltage for reading the non-volatile memory. The controller is configured to implement the artificial neural network.

The non-volatile memory may be a flash memory.

The artificial neural network may be a feed-forward neural network, a reinforcement learning network, a long short-term memory network, a recurrent neural network, or any combinations thereof.

The controller may be on a single semiconductor die.

The controller may have a prediction buffer configured to (A) store N sets of configuration parameters generated by the artificial neural network, N being an integer greater than 1, and (B) select one the N sets as the M configuration parameters.

The prediction buffer may be configured to select said one of the N sets based on condition features of the non-volatile memory.

The prediction buffer may be configured to select said one of the N sets based on (A) operation features of the non-volatile memory and (B) decoding status features of a decoder of the controller.

Inputs to the artificial neural network may be selected from a group consisting of condition features of the non-volatile memory, operation features of the non-volatile memory, decoding status features of a decoder of the controller, and any combinations thereof.

The condition features of the non-volatile memory may be selected from the group consisting of WE (write erase) count, data retention condition, data-read temperature, data-write temperature, block status, plane index, block index, wordline index, page index, and any combinations thereof.

The operation features of the non-volatile memory may be selected from the group consisting of read time of a page, program time of a page, erase time of a block, 1 s count of raw data of a page, and any combinations thereof.

The decoding status features may be selected from the group consisting of page decoding status vector, 1 to 0 error number array, 0 to 1 error number array, iteration number array, and any combinations thereof.

The controller may have (A) a control engine configured to control the non-volatile memory, and (B) a decoder configured to decode data read from the non-volatile memory. The controller is configured to use the M configuration parameters in interacting with the non-volatile memory by configuring the control engine using a first subset of the M configuration parameters, the first subset being selected from the group consisting of threshold voltages for reading the non-volatile memory, read failure probability, erase failure probability, program failure probability, and any combinations thereof. The controller is configured to use the M configuration parameters in interacting with the non-volatile memory by configuring the decoder using a second subset of the M configuration parameters, the second subset being selected from the group consisting of scaling factors, maximum iteration number, input LLR (log-likelihood ratio) values, and any combinations thereof.

The controller may be part of a system that is a solid-state drive (SSD), a flash drive, a mother board, a processor, a computer, a server, a gaming device, or a mobile device.

A method of using the controller includes: generating with the artificial neural network the M configuration parameters, wherein at least one of the M configuration parameters is not a threshold voltage for reading the non-volatile memory; and then using with the controller the M configuration parameters in interacting with the non-volatile memory.

Generating the M configuration parameters may include implementing the artificial neural network with the controller.

Generating the M configuration parameters may include storing in a prediction buffer N sets of configuration parameters generated by the artificial neural network, with N being an integer greater than 1; and then selecting with the prediction buffer one of the N sets as the M configuration parameters.

Selecting one of the N sets may be based on condition features of the non-volatile memory.

### BRIEF DESCRIPTION OF FIGURES

FIG. 1 schematically shows a memory system with an artificial neural network, according to an embodiment.

FIG. 2 shows a diagram of the artificial neural network, according to an embodiment.

FIG. 3 schematically shows the memory system, according to an alternative embodiment.

FIG. 4 shows a flowchart generalizing the operation of the controller of the memory system, according to an embodiment.

### DETAILED DESCRIPTION

### Memory System 100

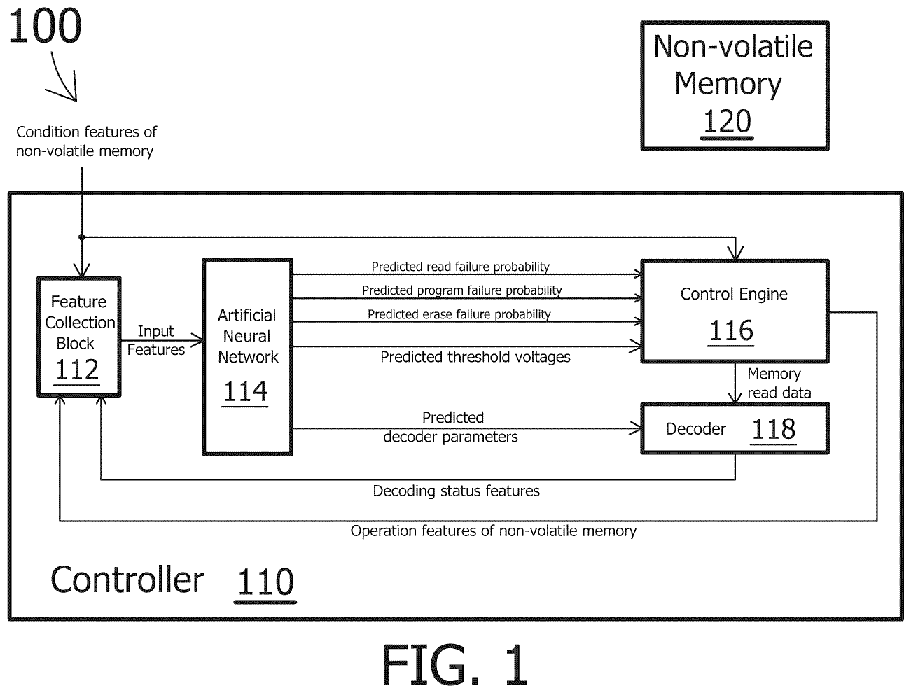

FIG. 1 schematically shows a memory system 100, according to an embodiment. The memory system 100 may include a controller 110 and a non-volatile memory 120. For simplicity, the communications between the controller 110 and the non-volatile memory 120 are not shown.

In an embodiment, the controller 110 may be part of a solid-state drive (SSD), a flash drive, a mother board, a processor, a computer, a server, a gaming device, or a mobile device (not shown).

### Non-Volatile Memory 120

In an embodiment, the non-volatile memory 120 may be a flash memory. A flash memory is a non-volatile storage device that retains data even when power is removed. Flash memory technology utilizes floating-gate transistors or charge trap technology to store data.

### Controller 110

In an embodiment, the controller 110 may manage the flow of data between the non-volatile memory 120 and external devices (e.g., a processor, not shown), allowing efficient and timely access to stored information. In an embodiment, the controller 110 may coordinate the reading and writing of data to and from the non-volatile memory 120, translating data requests by external devices into memory operations. In an embodiment, the controller 110 may implement caching, prefetching, and pipelining. In an embodiment, the controller 110 may perform error detection and correction, power management, and help to maintain overall system stability.

In an embodiment, the controller 110 may include a control engine 116 and a decoder 118. In an embodiment, the control engine 116 may perform the functions of the controller 110 described above, whereas the decoder 118 may perform the error detection and correction function.

In an embodiment, the controller 110 may further include a feature collection block 112 and an artificial neural network 114.

In an embodiment, the controller 110 may be formed on a single semiconductor die.

### Feature Collection Block 112

In an embodiment, the feature collection block 112 may receive as inputs (A) condition features of the non-volatile memory 120, for example, from the non-volatile memory 120, (B) operation features of the non-volatile memory 120, for example, from the control engine 116, and (C) decoding status features of the decoder 118, for example, from the decoder 118. In an embodiment, the feature collection block 112 may provide input features to the artificial neural network 114. In an embodiment, the input features may include the condition features of the non-volatile memory 120, the operation features of the non-volatile memory 120, and the decoding status features of the decoder 118.

### Artificial Neural Network 114

In an embodiment, the artificial neural network 114 may be a feed-forward neural network, a reinforcement learning network, a long short-term memory network, a recurrent neural network, or any combinations thereof.

In an embodiment, the artificial neural network 114 may receive as inputs the input features from the feature collection block 112. In an embodiment, the artificial neural network 114 may output (A) predicted read failure probability to the control engine 116, (B) predicted program failure probability to the control engine 116, (C) predicted erase failure probability to the control engine 116, (D) predicted threshold voltages (for reading the non-volatile memory 120) to the control engine 116, and (E) predicted decoder parameters to the decoder 118.

In an embodiment, the controller 110 may use these outputs (A), (B), (C), (D), and (E) of the artificial neural network 114 in interacting with the non-volatile memory 120. Specifically, in an embodiment, the controller 110 may use these outputs (A), (B), (C), (D), and (E) of the artificial neural network 114 to configure the control engine 116 and the decoder 118.

In an embodiment, the controller 110 may implement the artificial neural network 114. In an alternative embodiment, the artificial neural network 114 may be implemented by an external system (not shown) other than the memory system 100.

In an embodiment, the artificial neural network 114 may be implemented by hardware or firmware.

### Control Engine 116

In an embodiment, the control engine 116 may control the operation of the non-volatile memory 120.

In an embodiment, the control engine 116 may receive as inputs (A) the predicted read failure probability, the predicted program failure probability, the predicted erase failure probability, and the predicted threshold voltages (for reading the non-volatile memory 120) from the artificial neural network 114, and (B) the condition features of the non-volatile memory 120 from non-volatile memory 120. In an embodiment, the control engine 116 may provide as outputs (A) memory read data to the decoder 118, and (B) the operation features of the non-volatile memory 120 to the feature collection block 112.

### Decoder 118

In an embodiment, the decoder 118 may detect and/or correct errors that may occur to the data in the non-volatile memory 120.

In an embodiment, the decoder 118 may receive as inputs (A) the memory read data from the control engine 116 and (B) the predicted decoder parameters from the artificial neural network 114. In an embodiment, the decoding status features of the decoder 118 are provided to the feature collection block 112.

More about Artificial Neural Network 114

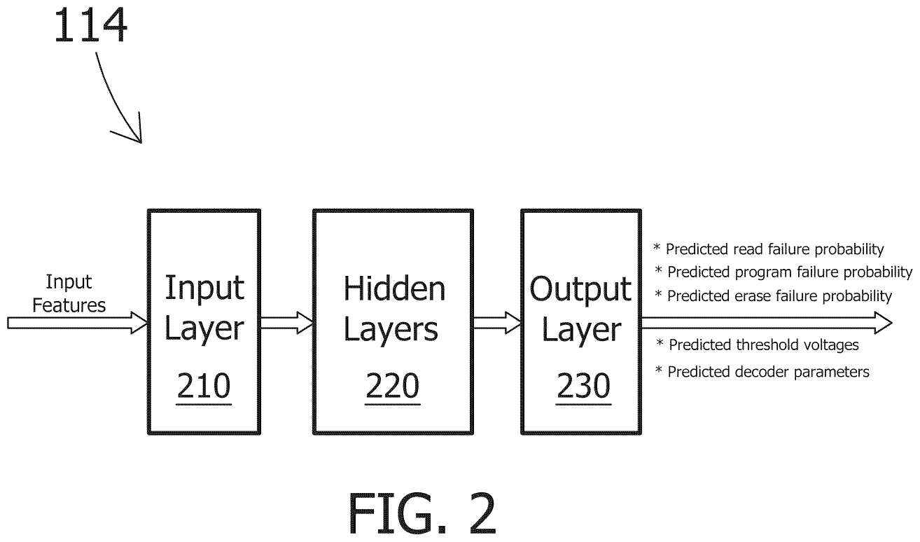

In an embodiment, with reference to FIG. 2, the artificial neural network 114 may include (A) an input layer 210, (B) hidden layers 220, and (C) an output layer 230.

### Input Layer 210

In an embodiment, with reference to FIG. 1 and FIG. 2, the input layer 210 may receive as inputs the input features from the feature collection block 112.

In an embodiment, the input features from the feature collection block 112 may include: (A) the condition features of the non-volatile memory 120, (B) the operation features of the non-volatile memory 120, and (C) the decoding status features of the decoder 118.

Specifically, in an embodiment, group (A) (i.e., the condition features of the non-volatile memory 120) may include: WE (write-erase) count, data retention condition, data-read temperature, data-write temperature, block status (open block or closed block), plane index, block index, wordline index, and page index.

Specifically, in an embodiment, group (B) (i.e., the operation features of the non-volatile memory 120) may include: read time of a page, program time of a page, erase time of a block, and 1 s count of raw data of a page.

Specifically, in an embodiment, group (C) (i.e., the decoding status features of the decoder 118) may include: page decoding status vector, 1 to 0 error number array, 0 to 1 error number array, and iteration number array.

For example, assume that a page has C ECC (Error Correction Code) codewords (C is a positive integer). As a result, the page decoding status vector consists of C-bit binary data. When the i-th bit is 1, the i-th codeword can be decoded successfully.

Also as a result, the 0 to 1 error number array has C integers. When the i-th codeword can be decoded successfully, the i-th number is valid and is equal to the 0 to 1 error number of the i-th codeword of the page reported by the decoder 118. Here, the 0 to 1 error number is the number of bits which is 0 before decoding and 1 after decoding.

Also as a result, the 1 to 0 error number array has C integers. When the i-th codeword can be decoded successfully, the i-th number is valid and is equal to the 1 to 0 error number of the i-th codeword of the page reported by the decoder 118. Here, the 1 to 0 error number is the number of bits which is 1 before decoding and 0 after decoding.

Also as a result, the iteration number array has C integers. When the i-th codeword can be decoded successfully, the i-th number is valid and is equal to the iteration number of the i-th codeword of the page reported by the decoder 118.

### Hidden Layers 220

In an embodiment, the hidden layers 220 may be between the input layer 210 and the output layer 230. In an embodiment, each hidden layer 220 may include multiple neurons which receive data from the previous layer and generate outputs for the next layer.

### Output Layer 230

In an embodiment, the output layer 230 may generate as outputs (A) the predicted read failure probability to the control engine 116, (B) the predicted program failure probability to the control engine 116, (C) the predicted erase failure probability to the control engine 116, (D) the predicted threshold voltages (for reading the non-volatile memory 120) to the control engine 116, and (E) the predicted decoder parameters to the decoder 118.

In an embodiment, the predicted threshold voltages of (D) mentioned above may include a threshold voltage for SLC (single level cells), 3 threshold voltages for MLC (multiple level cells), 7 threshold voltages for TLC (triple level cells), and 15 threshold voltages for QLC (quadruple level cells).

In an embodiment, the predicted decoder parameters of (E) mentioned above may include scaling factors for the min-sum algorithm, maximum iteration number, and input LLR (log-likelihood ratio) values.

In an embodiment, the predicted configuration parameters of (A), (B), (C), (D), and (E) mentioned above (i.e., the outputs of the output layer 230) may be used by the controller 110 to configure the control engine 116 and the decoder 118 of the controller 110. As a result, the predicted configuration parameters of (A), (B), (C), (D), and (E) mentioned above can be collectively referred to as M configuration parameters (with M being a positive integer).

In an embodiment, the controller 110 may use a first subset of the M configuration parameters to configure the control engine 116 and use a second subset of the M configuration parameters to configure the decoder 118. Note that the first subset and the second subset may overlap (i.e., they may share at least a common configuration parameter). Note that by definition, X is a subset of Y if all elements of X are also elements of Y.

In an embodiment, the first subset of the M configuration parameters may include the predicted configuration parameters of (A), (B), (C), and (D) mentioned above. In an embodiment, the second subset of the M configuration parameters may include the predicted configuration parameters of (E) mentioned above.

### Predicted Threshold Voltages

Note that the closer a threshold voltage (for reading the non-volatile memory 120) is to the optimal point, the fewer errors there will be in a page of the non-volatile memory 120. A page with more errors requires more effort (resulting in increased energy consumption and latency) to recover the data, thereby leading to worse performance in non-volatile storage of the memory system 100.

### Bad Block Prediction

Note that during the lifetime of the memory system 100, some blocks of the non-volatile memory 120 will accumulate errors over time, eventually rendering them as bad blocks that cannot be read, programmed, or erased. If a bad block is not identified in a timely manner, the data stored on it will be lost.

### Predicted Decoder Parameters

Note that poor predicted decoder parameters for configuring the decoder 118 will degrade error correction performance, including both codeword frame error rate and average iteration number.

### Operation of the Controller 110

In an embodiment, with reference to FIG. 1, the controller 110 may operate as follows. Firstly, the controller 110 may implement the artificial neural network 114 thereby causing the artificial neural network 114 to receive the input features and generate the M configuration parameters based on the input features. Then, in an embodiment, the controller 110 may use the M configuration parameters in interacting with the non-volatile memory 120. Specifically, in an embodiment, the controller 110 may use the M configuration parameters to configure the control engine 116 and the decoder 118.

In an embodiment, at least one of the M configuration parameters may not be a threshold voltage for reading the non-volatile memory 120.

### Multiple Sets of Configuration Parameters

In an embodiment, with reference to FIG. 1, the M configuration parameters may be the only set of configuration parameters generated by the artificial neural network 114 and then used by the controller 110 in interacting with the non-volatile memory 120.

In an alternative embodiment, the M configuration parameters used by the controller 110 in interacting with the non-volatile memory 120 may be one of N sets of configuration parameters generated by the artificial neural network 114 (N being an integer greater than 1).

Specifically, in an embodiment, the artificial neural network 114 may generate the N sets of configuration parameters simultaneously based on the input features from the feature collection block 112, with each set of the N sets being similar to the M configuration parameters. In other words, each set of the N sets may include predicted read failure probability, predicted program failure probability, predicted erase failure probability, predicted threshold voltages, and predicted decoder parameters. Next, in an embodiment, one of the N sets may be selected to be the M configuration parameters.

As a first example, assume M=10 and N=16. If the WE count of the input features is 1000, then the artificial neural network 114 may simultaneously generate N=16 sets of configuration parameters for WE count ranging from 1001 to 1016, with each set of the N=16 sets including M=10 configuration parameters.

As a second example, assume M=10 and N=32. If the page index of the input features is 512, then the artificial neural network 114 may simultaneously generate N=32 sets of configuration parameters for page index ranging from 513 to 544, with each set of the N=32 sets including M=10 configuration parameters.

As a third example, assume M=10 and N=16. If the WE count and page index of the input features are 1000 and 512 respectively, then the artificial neural network 114 may simultaneously generate N=16 sets of configuration parameters for WE count ranging from 1001 to 1004 and for page index ranging from 513 to 516, with each set of the N=16 sets including M=10 configuration parameters.

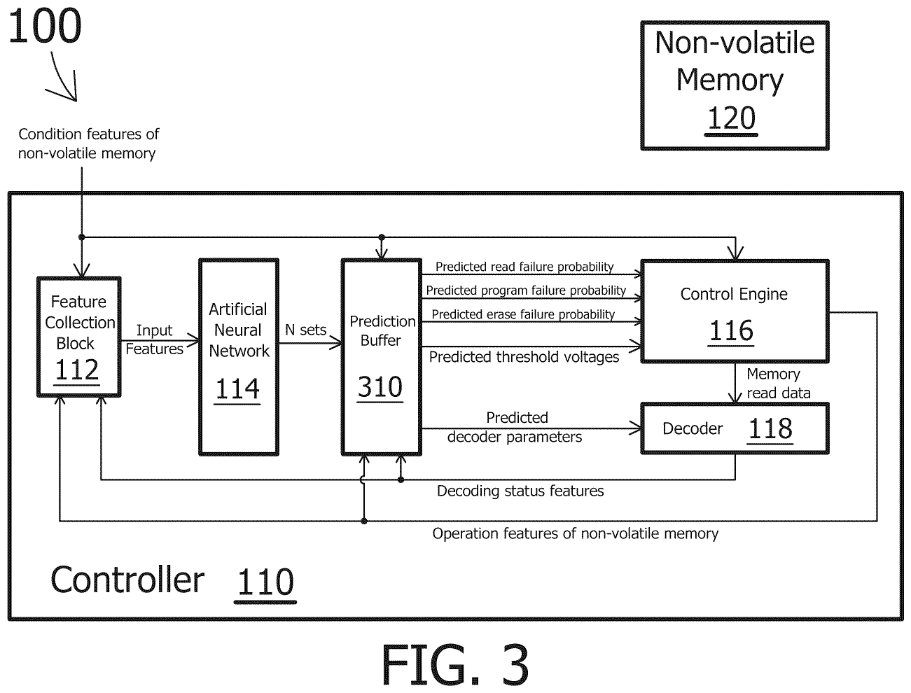

FIG. 3 schematically shows the memory system 100, according to the alternative embodiment described above. Specifically, in an embodiment, the controller 110 may include a prediction buffer 310 configured to (A) store the N sets of configuration parameters generated by the artificial neural network 114 and then (B) select one of the N sets as the M configuration parameters to be used by the controller 110 in interacting with the non-volatile memory 120.

In an embodiment, with reference to FIG. 3, the prediction buffer 310 may select said one of the N sets of configuration parameters based on the condition features of the non-volatile memory 120.

In an embodiment, the prediction buffer 310 may select said one of the N sets of configuration parameters based on (A) the operation features of the non-volatile memory 120 (e.g., as received from the control engine 116) and (B) the decoding status features of the decoder 118 (e.g., as received from the decoder 118).

### Flowchart Generalizing the Operation of Controller 110

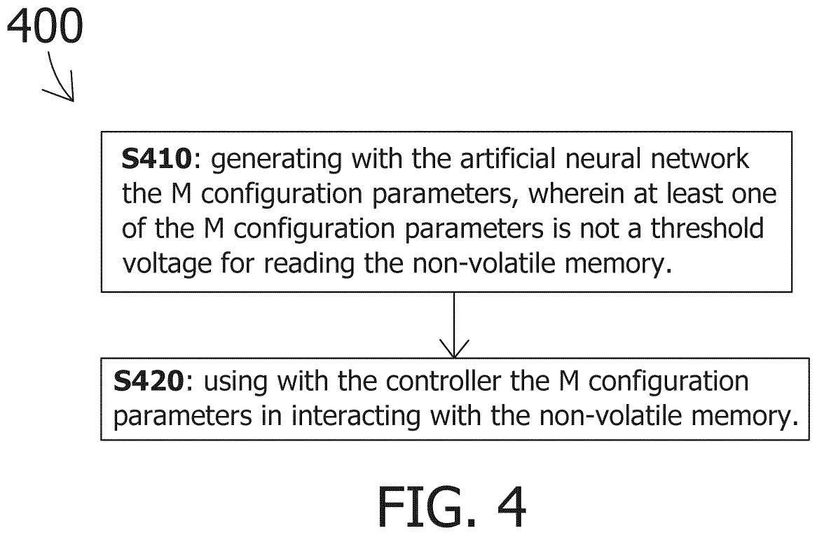

FIG. 4 is a flowchart 400 generalizing the operation of the controller 110, according to an embodiment. In step S410, the operation may include generating with the artificial neural network the M configuration parameters, wherein at least one of the M configuration parameters is not a threshold voltage for reading the non-volatile memory. For example, in the embodiments described above, with reference to FIG. 1, the artificial neural network 114 generates the M configuration parameters, wherein at least one of the M configuration parameters is not a threshold voltage for reading the non-volatile memory 120.

In step 420, the method may include using with the controller the M configuration parameters in interacting with the non-volatile memory. For example, in the embodiments described above, with reference to FIG. 1, the controller 110 uses the M configuration parameters in interacting with the non-volatile memory 120.

While various aspects and embodiments have been disclosed herein, other aspects and embodiments will be apparent to those skilled in the art. The various aspects and embodiments disclosed herein are for purposes of illustration and are not intended to be limiting, with the true scope and spirit being indicated by the following claims.

What is claimed is:

1. A controller, configured to generate M configuration parameters using an artificial neural network, M being a positive integer, and configured to use the M configuration parameters in interacting with a non-volatile memory,
wherein at least one of the M configuration parameters is not a threshold voltage for reading the non-volatile memory, and
wherein the controller is configured to implement the artificial neural network.

2. The controller of claim 1, wherein the non-volatile memory is a flash memory.

3. The controller of claim 1, wherein the artificial neural network is a feed-forward neural network, a reinforcement learning network, a long short-term memory network, a recurrent neural network, or any combinations thereof.

4. The controller of claim 1, wherein the controller is on a single semiconductor die.

5. The controller of claim 1, comprising a prediction buffer configured to:
(A) store N sets of configuration parameters generated by the artificial neural network, N being an integer greater than 1, and
(B) select one the N sets as the M configuration parameters.

6. The controller of claim 5, wherein the prediction buffer is configured to select said one of the N sets based on condition features of the non-volatile memory.

7. The controller of claim 5, wherein the prediction buffer is configured to select said one of the N sets based on (A) operation features of the non-volatile memory and (B) decoding status features of a decoder of the controller.

8. The controller of claim 6, wherein the condition features of the non-volatile memory are selected from the group consisting of WE (write erase) count, data retention condition, data-read temperature, data-write temperature, block status, plane index, block index, wordline index, page index, and any combinations thereof.

9. The controller of claim 7, wherein the operation features of the non-volatile memory are selected from the group consisting of read time of a page, program time of a page, erase time of a block, 1 s count of raw data of a page, and any combinations thereof.

10. The controller of claim 7, wherein the decoding status features are selected from the group consisting of page decoding status vector, 1 to 0 error number array, 0 to 1 error number array, iteration number array, and any combinations thereof.

11. The controller of claim 1, wherein inputs to the artificial neural network are selected from a group consisting of condition features of the non-volatile memory, operation features of the non-volatile memory, decoding status features of a decoder of the controller, and any combinations thereof.

12. The controller of claim 11, wherein the condition features of the non-volatile memory are selected from the group consisting of WE (write erase) count, data retention condition, data-read temperature, data-write temperature, block status, plane index, block index, wordline index, page index, and any combinations thereof.

13. The controller of claim 11, wherein the operation features of the non-volatile memory are selected from the group consisting of read time of a page, program time of a page, erase time of a block, 1 s count of raw data of a page, and any combinations thereof.

14. The controller of claim 11, wherein the decoding status features are selected from the group consisting of page decoding status vector, 1 to 0 error number array, 0 to 1 error number array, iteration number array, and any combinations thereof.

15. The controller of claim 1, comprising (A) a control engine configured to control the non-volatile memory, and (B) a decoder configured to decode data read from the non-volatile memory,
wherein the controller is configured to use the M configuration parameters in interacting with the non-volatile memory by configuring the control engine using a first subset of the M configuration parameters, the first subset being selected from the group consisting of threshold voltages for reading the non-volatile memory, read failure probability, erase failure probability, program failure probability, and any combinations thereof, and
wherein the controller is configured to use the M configuration parameters in interacting with the non-volatile memory by configuring the decoder using a second subset of the M configuration parameters, the second subset being selected from the group consisting of scaling factors, maximum iteration number, input LLR (log-likelihood ratio) values, and any combinations thereof.

16. A system, comprising the controller of claim 1, wherein the system is a solid-state drive (SSD), a flash drive, a mother board, a processor, a computer, a server, a gaming device, or a mobile device.

17. A method of using the controller of claim 1, comprising:
generating with the artificial neural network the M configuration parameters, wherein at least one of the M configuration parameters is not a threshold voltage for reading the non-volatile memory; and then
using with the controller the M configuration parameters in interacting with the non-volatile memory.

18. The method of claim 17, wherein said generating the M configuration parameters comprises implementing the artificial neural network with the controller.

19. The method of claim 17, wherein the non-volatile memory is a flash memory.

20. The method of claim 17, wherein said generating the M configuration parameters comprises:
storing in a prediction buffer N sets of configuration parameters generated by the artificial neural network, with N being an integer greater than 1; and then
selecting, with the prediction buffer, one of the N sets as the M configuration parameters.

21. The method of claim 20, wherein said selecting is based on condition features of the non-volatile memory.

22. The method of claim 20, wherein said selecting is based on (A) operation features of the non-volatile memory and (B) decoding status features of a decoder of the controller.
